(19) United States
(12) Patent Application Publication
(10) Pub. No.: US 2014/0118080 A1
(43) Pub. Date: May 1, 2014

(54) FREQUENCY SYNTHESIZER

(71) Applicant: PANASONIC CORPORATION, Osaka (JP)

(72) Inventors: Atsushi OHARA, Shiga (JP); Hidetoshi YAMASAKI, Mie (JP)

(73) Assignee: PANASONIC CORPORATION, Osaka (JP)

(21) Appl. No.: 14/149,481

(22) Filed: Jan. 7, 2014

Related U.S. Application Data
(63) Continuation of application No. PCT/JP2012/000215, filed on Jan. 16, 2012.

(30) Foreign Application Priority Data
Jul. 11, 2011 (JP) 2011-153158

(51) Int. Cl. H03L 7/099

(52) U.S. Cl. CPC H03L 7/0991
USPC 331/36 C; 331/1 A

(57) ABSTRACT

A digitally controlled frequency synthesizer less influenced by disturbance noise is provided without using a ΔΣ modulator. The frequency synthesizer, whose oscillation frequency is digitally controlled, includes a loop gain control section configured to generate digital control data for controlling a loop gain of the frequency synthesizer; a DA conversion section configured to convert lower bits of the digital control data to an analog voltage; and an oscillation section configured to oscillate at a frequency corresponding to higher bits of the digital control data and the analog voltage output from the DA conversion section.

### CROSS-REFERENCE TO RELATED APPLICATIONS

This is a continuation of International Application No. PCT/JP2012/000215 filed on Jan. 16, 2012, which claims priority to Japanese Patent Application No. 2011-153158 filed on Jul. 11, 2011. The entire disclosures of these applications are incorporated by reference herein.

### BACKGROUND

The present disclosure relates to frequency synthesizers used for semiconductor integrated circuits.

In recent years, with development in miniaturization of CMOS manufacturing processes, researches for driving at lower voltages, reducing characteristic variations, miniaturizing circuits, etc., by replacing all or part of analog circuits with digital circuits have been developed. With respect to frequency synthesizers as well, digitalization of all the elements such as phase comparators and loop filters have been researched.

For example, a known frequency synthesizer includes a voltage controlled oscillator (VCO), whose frequency is controlled by an analog voltage, performs phase comparison between a reference signal and an oscillation frequency signal of the VCO and filtering of the comparison result by digital processing, and controls the VCO by converting an output of a digital loop filter to the analog voltage with a DA converter (see, for example, the specification of U.S. Pat. No. 7,109,805). Another known frequency synthesizer includes a digitally controlled oscillator (DCO), whose frequency is controlled with a digital value being discrete numerical information, digitalizes phase information of an oscillation frequency signal of the DCO, and feeds back the digitalized information to the DCO via a phase comparator and a loop filter (see, for example, U.S. Pat. No. 7,046,098).

The oscillator (the VCO or the DCO) in each of the above-described frequency synthesizer includes a variable capacitive element whose capacitance is variable in accordance with an applied control voltage, and the oscillation frequency is controlled by adjusting the capacitance. FIG. 16A illustrates the relationship between the capacitance Cvr of the variable capacitive element in the oscillator and the control voltage Vc. FIG. 16B illustrates the relationship between the oscillation frequency f and the control voltage Vc. For example, where Vc=VH, Cvr=Co. Where Vc=VL(VL<VH), Cvr=Co+ΔC. On the other hand, where Vc=VL, f=fo. Where Vc=VH, f=fo+Δf.

VCOs are advantageous in continuously changing the oscillation frequency, but are disadvantageous in being greatly influenced by disturbance noise, since there is a need to use Vc in a range of the variable capacitive element, which is highly sensitive to capacitance changes. On the other hand, DCOs are advantageous in being less influenced by disturbance noise, since Vc is used in a range such as VH and VL of the variable capacitive element, which is less sensitive to capacitance changes.

The oscillation frequency of each DCO is changed discretely. In order to obtain a desired frequency, there is a need to provide more precise gradation in the oscillation frequency using a ΔΣ modulator. Use of a ΔΣ modulator causes problems such as quantization noise or an increase in current consumption due to high-speed ΔΣ modulation.

Therefore, there is a need for digitally controlled frequency synthesizers less influenced by disturbance noise and not requiring any ΔΣ modulator.

### SUMMARY

According to one aspect of the present disclosure, a frequency synthesizer whose oscillation frequency is digitally controlled includes a loop gain control section configured to generate digital control data for controlling a loop gain of the frequency synthesizer; a DA conversion section configured to convert lower bits of the digital control data to an analog voltage; and an oscillation section configured to oscillate at a frequency corresponding to higher bits of the digital control data and the analog voltage output from the DA conversion section.

With this configuration, since the oscillation of the oscillation section is controlled by performing the DA conversion of the lower bits of the digital control data, no ΔΣ modulator is needed. The oscillation is controlled using higher bits of digital values, thereby reducing the influence of disturbance noise.

The oscillation section may include a thermometer converter configured to convert the higher bits of the digital control data to a thermometer code, a plurality of voltage selection circuits, each corresponding to one of a plurality of given bits of the thermometer code, and configured to selectively output either one of a voltage of corresponding one of the given bits or the analog voltage output from the DA conversion section, and a plurality of variable capacitive elements coupled in parallel, each having capacitance controlled in accordance with a voltage of one of the bits of the thermometer code, which is applied to none of the voltage selection circuits, or an output voltage of corresponding one of the plurality of voltage selection circuit.

The DA conversion section may include a plurality of DA converters each configured to convert corresponding one of the lower bits of the digital control data to an analog voltage, and each of the plurality of voltage selection circuits selectively outputs any one of the voltage of the corresponding one of the given bits of the thermometer code or the analog voltages output from the DA plurality of converters.

More specifically, the plurality of DA converters may output different analog voltages from a common input. Output voltage ranges of the plurality of DA converters may be different from each other, and narrower than voltage change ranges of the bits of the thermometer code.

A control signal instructing the voltage selection circuits to select the analog voltage output from the DA conversion section may be temporally discretely active.

The oscillation section may include LPFs coupled to outputs of the voltage selection circuits. Similarly, the frequency synthesizer may further include an LPF coupled to an output of the DA conversion section.

The oscillation section may include a plurality of first variable capacitive elements coupled in parallel, each having capacitance controlled with one of the higher bits of the digital control data, and a second variable capacitive element coupled in parallel to the plurality of first variable capacitive elements, and having capacitance controlled with the analog voltage output from the DA conversion section. A change amount of the capacitance of the second variable capacitive element may correspond to weighting of a least significant bit of the higher bits.

### BRIEF DESCRIPTION OF THE DRAWINGS

FIG. 1 illustrates a configuration of a frequency synthesizer according to a first embodiment.

FIG. 2 illustrates a configuration of a part of the frequency synthesizer according to the first embodiment.

FIG. 3 illustrates a configuration of a part of a frequency synthesizer according to a variation of the first embodiment.

FIG. 4 illustrates a configuration of a part of a frequency synthesizer according to a second embodiment.

FIGS. 5A and 5B illustrate operation of the frequency synthesizer according to the second embodiment.

FIGS. 6A and 6B illustrate control for preventing simultaneous turn-on of terminals of voltage selection circuits in the second embodiment.

FIG. 7 illustrates a configuration of a part of a frequency synthesizer according to a third embodiment.

FIGS. 8A-8C illustrate operation of the frequency synthesizer according to the third embodiment.

FIGS. 9A and 9B illustrate operation of the frequency synthesizer according to the third embodiment.

FIGS. 10A and 10B are graphs illustrating the relation between digital control data and a change in capacitance.

FIGS. 11A and 11B illustrate control for preventing simultaneous turn-on of terminals of voltage selection circuits in the third embodiment.

FIGS. 12A-12C illustrate operation of a frequency synthesizer according to a variation of the third embodiment.

FIGS. 13A and 13B illustrate operation of a frequency synthesizer according to a variation of the third embodiment.

FIG. 14 illustrates the configuration of a part of a frequency synthesizer according to a fourth embodiment.

FIGS. 15A-15C illustrate operation of the frequency synthesizer according to the fourth embodiment.

FIGS. 16A and 16B are graphs illustrating the relation between the capacitance and the control voltage, and the relation between the oscillation frequency and the control voltage of a variable capacitive element in an oscillation section, respectively.

### DETAILED DESCRIPTION

### First Embodiment

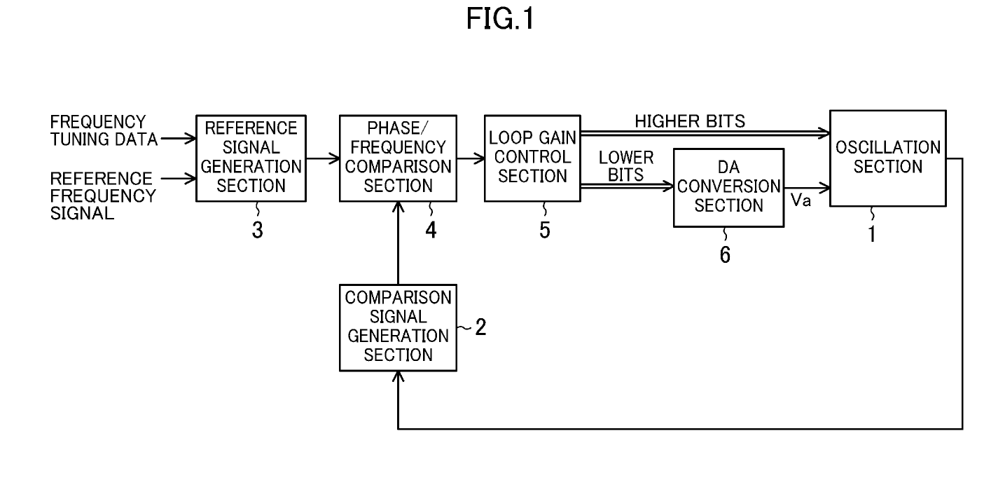

A first embodiment of the present disclosure will be described hereinafter with reference to the drawings. FIG. 1 illustrates a circuit configuration of a frequency synthesizer according to the first embodiment. As shown in FIG. 1, the frequency synthesizer according to this embodiment includes an oscillation section 1, a comparison signal generation section 2, a reference signal generation section 3, a phase/frequency comparison section 4, a loop gain control section 5, and a DA conversion section 6. An oscillation output of the oscillation section 1 is subjected to processing such as frequency division or integration at the comparison signal generation section 2 to be converted to a comparison signal. The comparison signal is compared to a reference signal at the phase/frequency comparison section 4. The reference signal is, for example, generated from frequency tuning data and a reference frequency signal, which are input to the reference signal generation section 3. The phase/frequency comparison section 4 compares the phases and/or frequencies of the comparison signal and the reference signal, and outputs a comparison result corresponding to the difference(s). The comparison result is controlled to be a proper loop gain by the loop gain control section 5, and output as multi-bit digital control data.

In this embodiment, the higher bits of the digital control data control the oscillation frequency of the oscillation section 1 without change. The lower bits are converted to an analog signal Va at the DA conversion section 6. Va controls the oscillation frequency of the oscillation section 1.

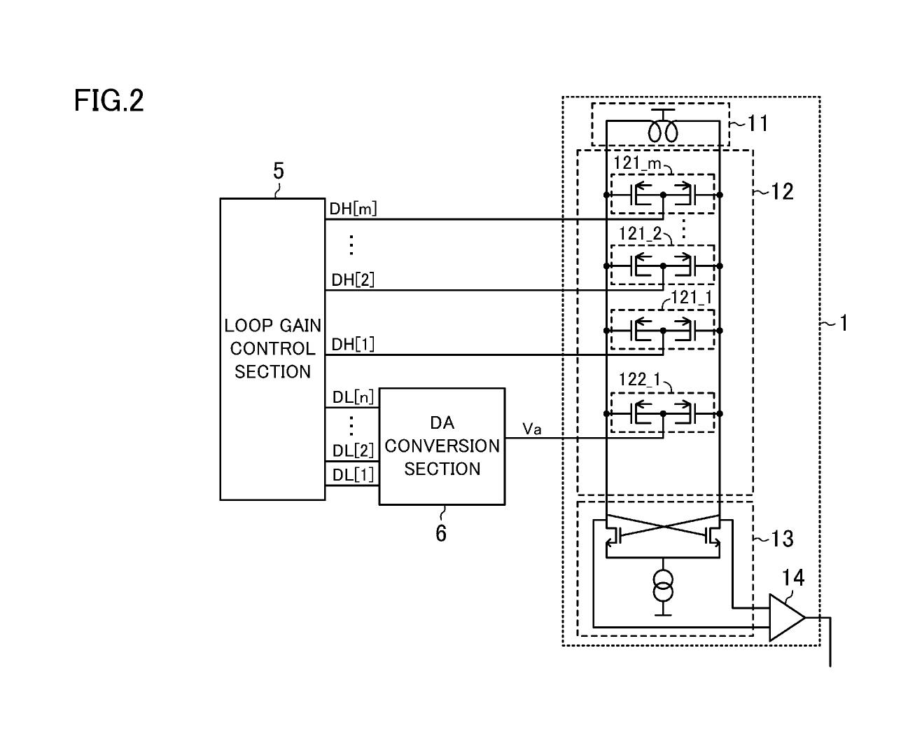

FIG. 2 illustrates a configuration of a part of the frequency synthesizer according to this embodiment. In FIG. 2, an output of the loop gain control section 5 is binary data including higher m bits DH[1]-DH[m] and lower n bits DL[1]-DL[n]. The oscillation section 1 includes an inductor 11, a variable capacitive section 12, a negative resistor 13, and an output buffer 14. Where the inductance generated by the inductor 11 is L and the capacitance generated mainly by the variable capacitive section 12 is C, the output frequency f of the oscillation section 1 is expressed by the following equation.

$$f = \frac{1}{2 π \sqrt{LC}} \qquad ( 1 )$$

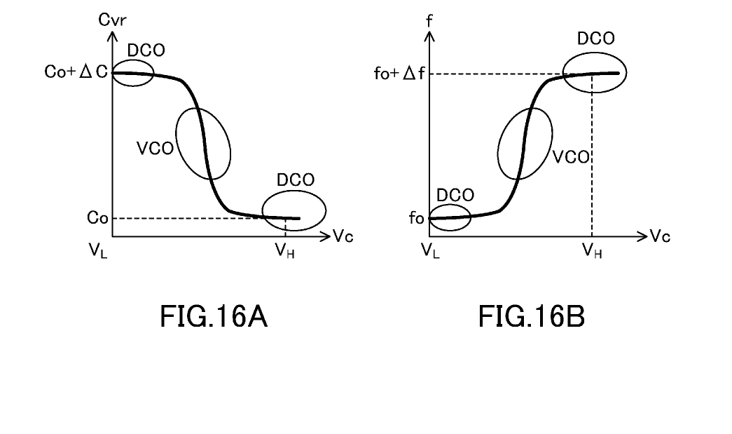

The variable capacitive section 12 includes a plurality of variable capacitive elements 121_1-121_{—}m, and 122_1, which are coupled in parallel. The capacitance of each variable capacitive element changes with the control voltage. Accordingly, the oscillation frequency of the oscillation section 1 changes. The relation between the capacitance Cvr of each variable capacitive element in the oscillation section 1 and the control voltage Vc, and the relation between the oscillation frequency f of the oscillation section 1 and the control voltage Vc are as shown in FIGS. 16A and 16B.

The variable capacitive elements 121_1-121_{—}m are directly controlled with the higher m bits DH[1]-DH[m] of the output of the loop gain control section 5. Therefore, the change amounts of the capacitance of the variable capacitive elements 121_2-121_{—}m are 2ΔC, 4ΔC, . . . 2^{m-1}ΔC using a change amount ΔC of the capacitance of the variable capacitive element 121_1 as a reference so that the change amounts of the capacitance of the variable capacitive elements 121_1-121_{—}m are at a binary ratio.

On the other hand, the DA conversion section 6 converts the lower n bits DL[1]-DL[n] of the output of the loop gain control section 5 to an analog voltage Va. Va controls the variable capacitive element 122_1. In this embodiment, the output voltage of the DA conversion section 6 ranges from the minimum of VL, which corresponds to the L level of each higher bit, to the maximum expressed by VH′=(2ⁿ−1)·ΔVao+VL. That is, the change amount of the capacitance of the variable capacitive element 122_1 is equal to the change amount of the capacitance of the variable capacitive element 121_1, where ΔVao is within the variable LSB range of the output voltage, i.e., the variable voltage range of the DA conversion section 6 corresponding to DL[1]. Where the voltage corresponding to the H level of each higher bit is VH, the following equation is obtained.

ΔVao=(VH−VL)/2ⁿ

The capacitance of the variable capacitive element 122_1 can be closely controlled by the lower bits in the above range as appropriate. For example, assume that the bit width m of the higher bits is 8, the bit width n of the lower bits is 8, and the digital control data changes from 0000 0000 1111 1111 to 0000 0001 0000 0000, i.e., the lower bits overflow and are carried to the higher bits. The voltage change from VH to VL corresponding to the LSB of the higher bits is equal to the value obtained by ΔVao×2ⁿ, thereby maintaining continuous control.

### Variation

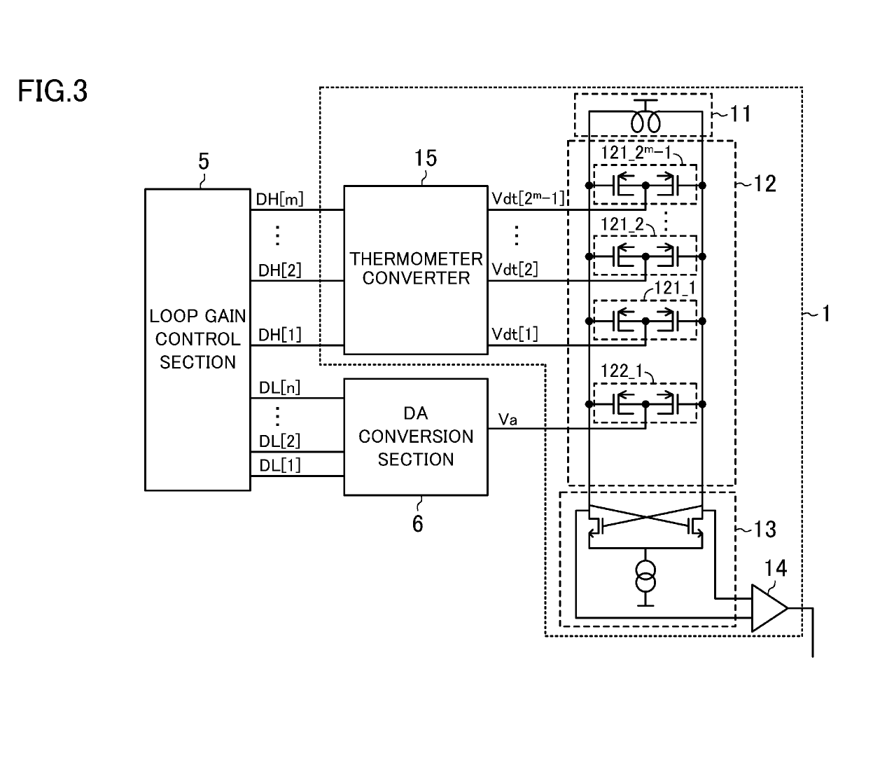

In the above description, the capacitance control using the higher bits is the binary control. In order to improve linearity, as shown in FIG. 3, the variable capacitive section 12 may include variable capacitive elements 121_1-121_2^{m}−1 having the same change amount of the capacitance. An oscillation section 1 may further include a thermometer converter 15 to convert higher bits to thermometer codes Vdt[1]-Vdt[2^{m}−1] and control the variable capacitive elements 121_1-121_2^{m}−1.

As shown in Japanese Unexamined Patent Publication No. 2009-10599, the higher bits may be further divided into higher and lower bits. Variable capacitive elements for the higher ones of the higher bits may have the change amounts of the capacitance obtained from the relation with the bit number of the lower ones of the higher bits. The higher and lower ones of the higher bits may be converted to thermometer codes to control the variable capacitive elements.

### Second Embodiment

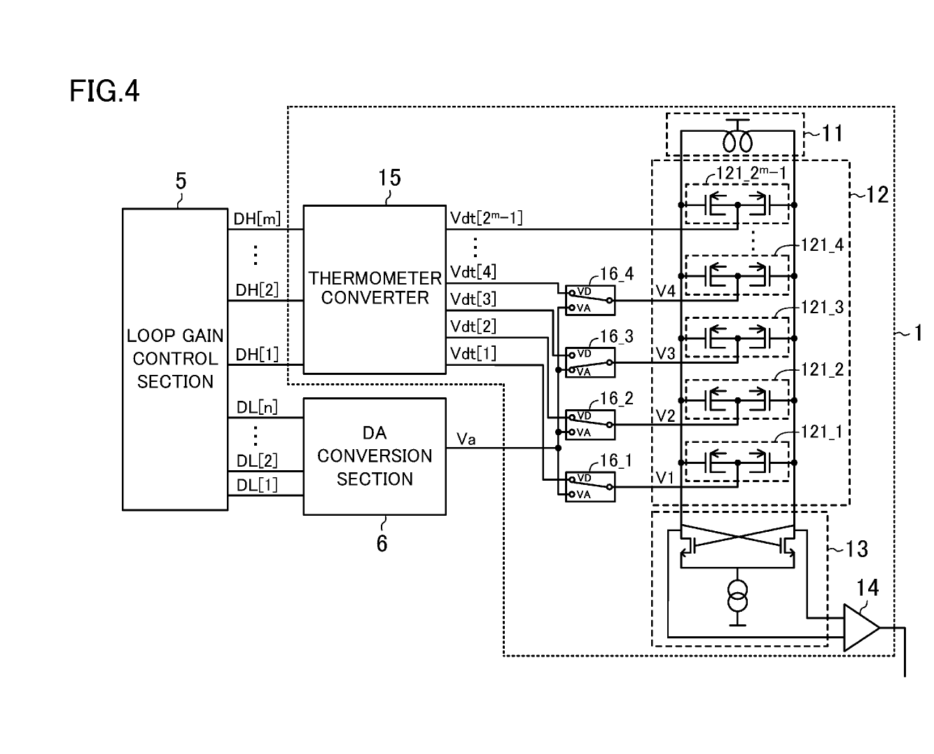

FIG. 4 illustrates a configuration of a part of a frequency synthesizer according to a second embodiment. The entire configuration is similar to that in the first embodiment. Differences from the first embodiment will be described below.

In the frequency synthesizer according to this embodiment, an oscillation section 1 includes voltage selection circuits 16_1-16_4, each of which corresponds to one of a plurality of given bits of a thermometer code, and selectively outputs either one of the voltage of corresponding one of the given bits or an analog voltage Va output from a DA conversion section 6. A variable capacitive section 12 includes a plurality of variable capacitive elements 121_1-121_2m−1, which are coupled in parallel. VA terminals of the voltage selection circuits 16_1-16_4 are coupled in common to the output Va of the DA conversion section 6. The respective VD terminals are coupled to the outputs Vdt[1]-Vdt[4] of a thermometer converter 15. Output voltages V1-V4 of the voltage selection circuits 16_1-16_4 control the variable capacitive elements 121_1-121_4.

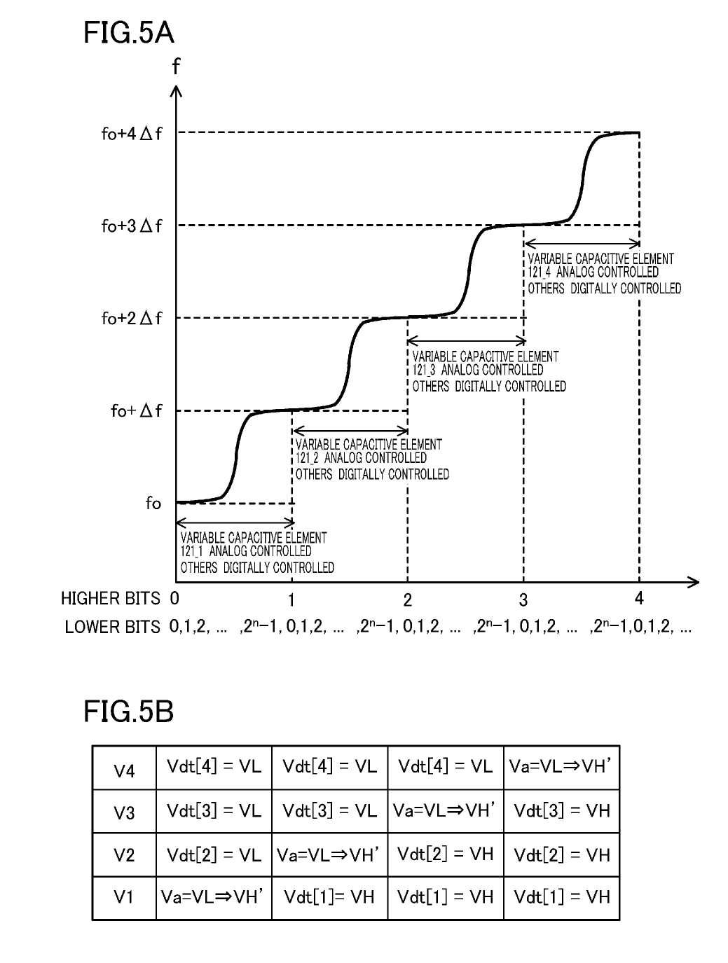

FIGS. 5A and 5B illustrate operation of the frequency synthesizer according to this embodiment. In the graph of FIG. 5A, the horizontal axis represents digital control data output from a loop gain control section 5, and the vertical axis represents the oscillation frequency of the oscillation section 1. FIG. 5B illustrates the output voltages V1-V4 of the voltage selection circuits 16_1-16_4.

Assume that the higher bits and the lower bits sequentially increase from zero. Where (higher bit, lower bit) is (0, 0), the oscillation frequency is expressed by f=fo. At this time, the voltage selection circuit 16_1 selects Va, and the voltage selection circuits 16_2-16_4 select Vdt[2]-Vdt[4], respectively. Then, the lower bits gradually increase, the control voltage V1 of the variable capacitive element 121_1 gradually increases. Accordingly, the capacitance of the variable capacitive element 121_1 decreases, and the oscillation frequency increases.

Next, assume that (higher bit, lower bit) of (0, 2ⁿ−1) changes to (1, 0). In this case, in the first embodiment, DH[1] controlling the variable capacitive element 121_1 different from the variable capacitive element 122_1 shown in FIG. 2 changes from VL to VH, and the control voltage Va of the variable capacitive element 122_1 gradually increases again from VL to VH′. In FIG. 2, where the change amount of the capacitance of the variable capacitive element 121_1 is completely equal to the change amount of the capacitance of the variable capacitive element 122_1, the voltage change from VH to VL corresponding to the LSB of the higher bits is ideally equal to the value obtained by ΔVao×2ⁿ. Therefore, the change in the oscillation frequency when the lower bits change from 0 to 2ⁿ−1, i.e., when Va changes to ΔVao×2ⁿ−1 is continuously followed by the change in the oscillation frequency when the higher bits change only by one, i.e., when Va changes to ΔVao×2ⁿ. Indeed, however, due to the relative variations of the elements, the change amount of the capacitance of the variable capacitive element 121_1 is not always completely identical with the change amount of the capacitance of the variable capacitive element 122_1. If the relative variations are great, the change in the oscillation frequency when Va controlling the variable capacitive element 122_1 changes to ΔVao×2ⁿ−1 is greater than the change in the oscillation frequency when Vdt[1] controlling the variable capacitive element 121_1 changes from VL to VH. That is, discontinuity of the oscillation frequency may occur.

To address the problem, in this embodiment, when (higher bit, lower bit) of (0, 2ⁿ−1) changes to (1, 0), the control voltage V1 of the variable capacitive element 121_1 is switched from Va to Vdt[1], where Vdt[1]=VH, and the control voltage V2 of the variable capacitive element 121_2 is switched from Vdt[2] to Va, where Vdt[2]=VL and Va=VL. Similarly, when (higher bit, lower bit) of (1, 2ⁿ−1) changes to (2, 0), the control voltage V2 of the variable capacitive element 121_2 is switched from Va to Vdt[2], and the control voltage V3 of the variable capacitive element 121_3 is switched from Vdt[3] to Va. When (higher bit, lower bit) of (2, 2ⁿ−1) changes to (3, 0), the control voltage V3 of the variable capacitive element 121_3 from Va to Vdt[3], and the control voltage V4 of the variable capacitive element 121_4 is switched from Vdt[4] to Va. This prevents the discontinuous change in the oscillation frequency.

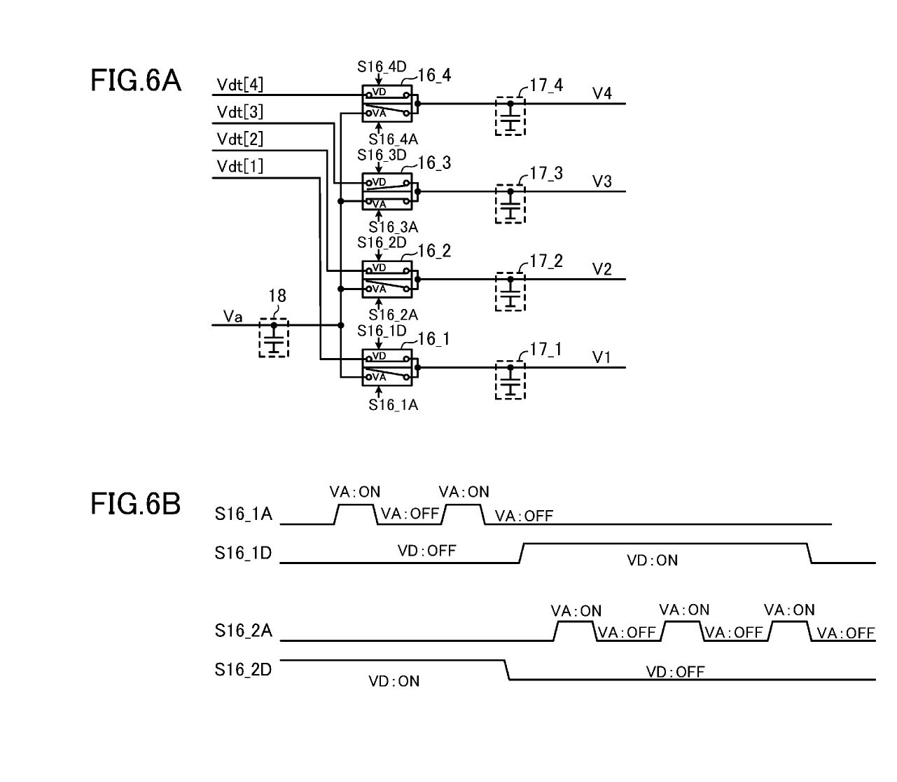

In each of the voltage selection circuits 16_1-16_4, the VA terminal and the VD terminal are transiently turned on at the same time. Malfunction caused by the simultaneous turn-off is preferably prevented. FIGS. 6A and 6B illustrate control for preventing the simultaneous turn-on of the VA terminals and the VD terminals of the voltage selection circuits 16_1-16_4. FIG. 6A illustrates more detailed configurations of the voltage selection circuits 16_1-16_4. FIG. 6B illustrates example timing of control signals of the voltage selection circuits 16_1 and 16_2. As shown in FIG. 6A, for example, in the voltage selection circuit 16_1, the on/off state of the VA terminal is controlled with a control signal S16_1A, and the on/off state of the VD terminal is controlled with a control signal S16_1D. Simultaneous activation of S16_1A and S16_1D is prevented, thereby preventing the simultaneous turn-on of the VA terminal and the VD terminal.

As shown in FIG. 6B, the signals S16_1A and S16_2A controlling the on/off state of the VA terminals may not be continuously active, but may be temporally discretely active. This reduces malfunction caused by a transient change in the output voltage Va at the moment of changing DL[1]-DL[n] input to the DA conversion section 6.

Since V1-V4 are control voltages of the variable capacitive elements, even when the VA terminal and the VD terminal of each voltage selection circuit are turned off at the same time, the voltage of the variable capacitive element before the turn-off is held. In addition, as shown in FIG. 6A, LPFs 17_1-17_4 being capacitive elements etc., may be added to the outputs of the voltage selection circuits 16_1-16_4 to reduce a voltage change due to leakage etc. Similarly, an LPF 18 being a capacitive element etc., may be added to the output of the DA conversion section 6 to reduce malfunction caused by transient response of the DA conversion section 6.

### Third Embodiment

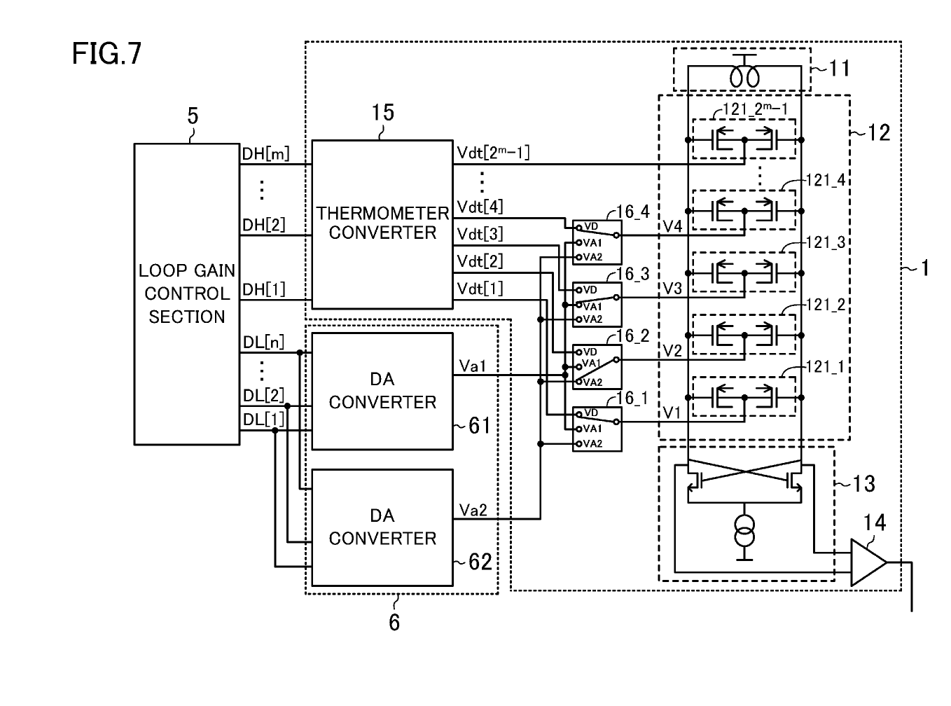

FIG. 7 illustrates a configuration of a part of a frequency synthesizer according to a third embodiment. The entire configuration is similar to that in the first embodiment. Differences from the first and second embodiments will be described below.

In the frequency synthesizer according to this embodiment, a DA conversion section 6 includes two DA converters 61 and 62 performing DA conversion of lower n bits DL[1]-DL[n] of an output of a loop gain control section 5. An oscillation section 1 includes voltage selection circuits 16_1-16_4, each of which corresponds to one of a plurality of given bits of a thermometer code, and selectively outputs any one of the voltage of corresponding one of the given bits, analog voltages Va1 or Va2 output from the DA converters 61 and 62. The VA1 terminals of the voltage selection circuits 16_1-16_4 are coupled in common to the output Va1 of the DA converter 61. The VA2 terminals are coupled in common to the output Va2 of the DA converter 62. The respective VD terminals are coupled to the outputs Vdt[1]-Vdt[4] of a thermometer converter 15. Output voltages V1-V4 of the voltage selection circuits 16_1-16_4 control variable capacitive elements 121_1-121_4, respectively.

The DA converters 61 and 62 have variable ΔVao. Specifically, ΔVao is switchable between (VH−VL)/2ⁿ and (VH−VL)/2ⁿ⁺¹.

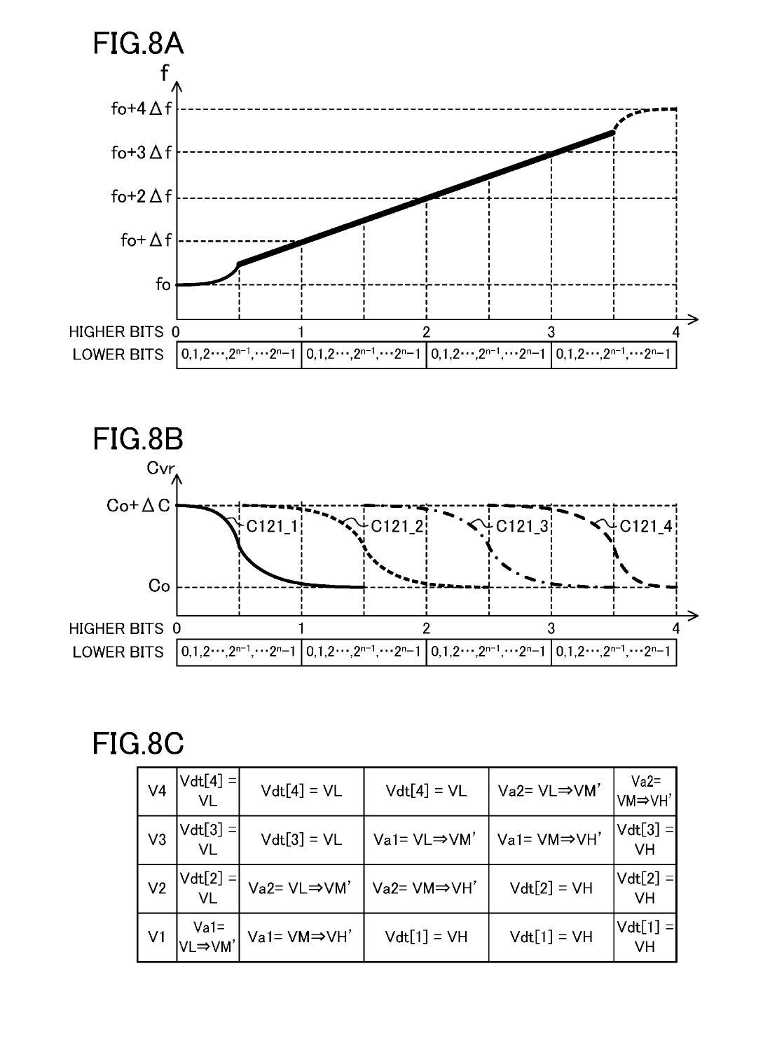

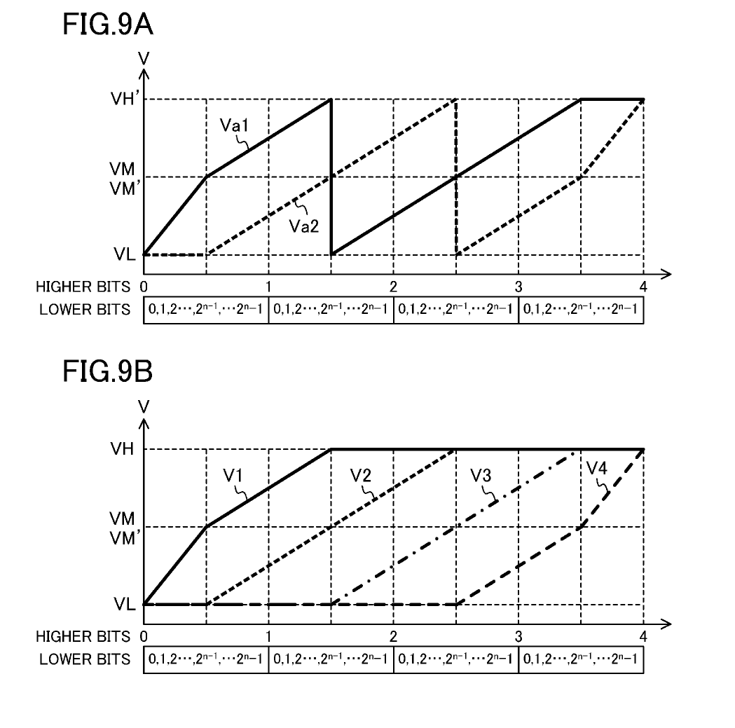

FIGS. 8A-8C, 9A, and 9B illustrate operation of the frequency synthesizer according to this embodiment. In each graph of FIGS. 8A, 8B, 9A, and 9B, the horizontal axis represents digital control data output from the loop gain control section 5. In FIG. 8A, the vertical axis represents the oscillation frequency of the oscillation section 1. In FIG. 8B, the vertical axis represents the capacitance of the variable capacitive elements 121_1-121_4. In FIG. 9A, the vertical axis represents values of Va1 and Va2. In FIG. 9B, the vertical axis represents values of V1-V4. In FIG. 8C, the vertical axis represents the output voltages V1-V4 of the voltage selection circuits 16_1-16_4.

Assume that the higher bits and the lower bits sequentially increase from zero. Where (higher bit, lower bit)=(0, 0), the oscillation frequency is expressed by f=fo. At this time, the voltage selection circuit 16_1 selects Va1, and the voltage selection circuits 16_2-16_4 select Vdt[2]-Vdt[4]. Then, when the lower bits gradually increase, the control voltage V1 of the variable capacitive element 121_1 gradually increases. Accordingly, the capacitance C121_1 of the variable capacitive element 121_1 decreases, and the oscillation frequency increases.

Next, when (higher bit, lower bit)=(0, 2ⁿ⁻¹1), i.e., when the lower bits increase to the half, Va1 changes from the initial minimum VL to the median VM′. VM′ is the value of Va1 where the lower bits is 2⁻¹−1. Then, when the lower bits further increase, V1 outputting Va1 increases from the median VM, and the voltage selection circuit 16_2 selects Va2, which increases from VL. VM is the value of Va1 where the lower bits is 2⁻¹. At this time, ΔVao of the DA converters 61 and 62 is switched from (VH−VL)/2ⁿ to (VH−VL)/2ⁿ⁺¹. As a result, the amount of the increase in Va1 corresponding to a change in the lower bits is half of that in the case where only Va1 increases. Therefore, as shown in FIGS. 8B and 9A, Va1 is closer to the maximum VH′ as (higher bit, lower bit) comes close to (1, 2ⁿ⁻¹), but C121_1 decreases.

When (higher bit, lower bit) is (1, 2ⁿ⁻¹), V1 is switched from Va1 to Vdt[1], where Vdt[1]=VH, and then, stable at C121_1=Co, and V3 is switched from Vdt[3] to Va1, where Vdt[3]=VL and Va1=VL. After that, Va1 increases from VL to VM′ as (higher bit, lower bit) comes close to (2, 2ⁿ⁻¹−1), and C121_3 decreases from Co+ΔC.

When (higher bit, lower bit) is (2, 2ⁿ⁻¹1), V2 is switched from Va2 to Vdt[2], where Vdt[2]=VH, and then, stable at C121_2=Co, and V4 is switched from Vdt[4] to Va2, where Vdt[4]=VL and Va2=VL. After that, Va2 increases from VL to VM′ toward (higher bit, lower bit)=(3, 2ⁿ⁻¹−1), and C121_4 decreases from Co+ΔC.

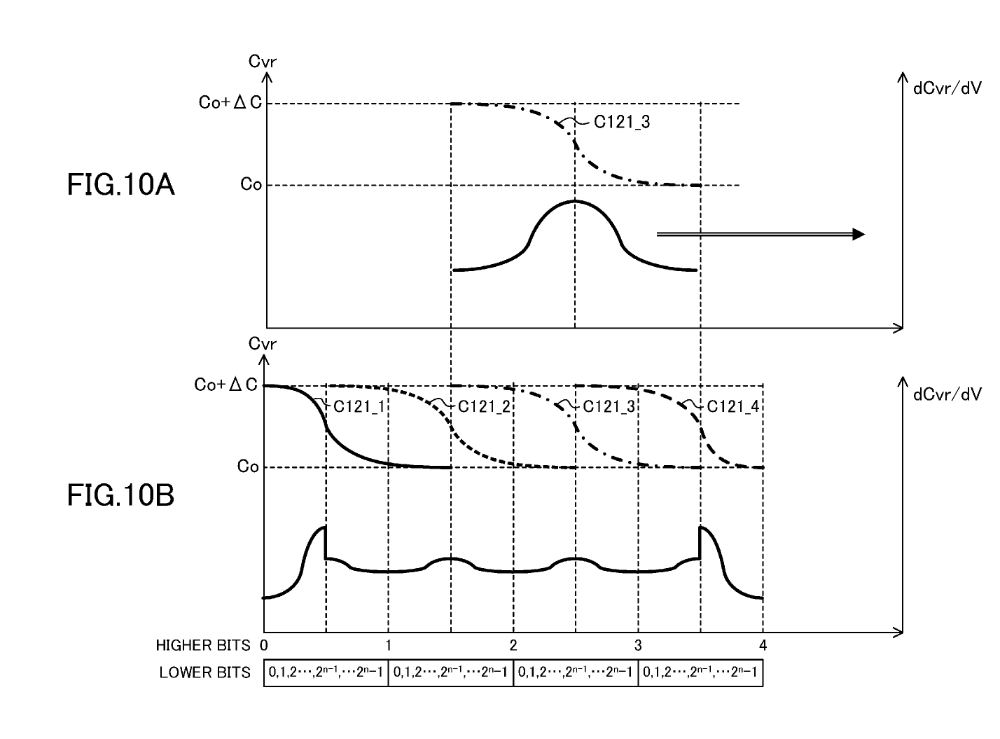

One of the variable capacitive elements, for example, the variable capacitive element 121_3 is used an example here. A change in the lower bits, i.e., a change dCvr in the capacitance C121_3 corresponding to the change dV in the control voltage is indicated by a curve shown in the bottom of FIG. 10A. The upper curve of FIG. 10A represents C121_3. As clear from FIG. 10A, the amount of change is great in the middle of the change in the capacitance.

The upper curves of FIG. 10B represent C121_1-C121_4, and the lower curved line represents a change in the synthesized capacitance of the variable capacitive elements 121_1-121_4. For example, in the middle of the change in which the amount of change in C121_2 is the greatest, the amounts of change in C121_1 and C121_3 are small. Similarly, in the middle of the change in which the amount of change in C121_3 is the greatest, the amounts of change in C121_2 and C121_4 are small. Thus, the change in the synthesized capacitance of the variable capacitive elements 121_1-121_4 is close to a flat shape from (higher bit, lower bit)=(0, 2ⁿ⁻¹) to (3, 2ⁿ⁻¹). The oscillation frequency of the oscillation section 1 varies like a straight line as shown in FIG. 8A. Therefore, the frequency synthesizer according to this embodiment is used to be locked in the range from (higher bit, lower bit)=(0, 2ⁿ⁻¹) to (3, 2ⁿ⁻¹), thereby reducing the amount of change in the frequency in accordance with the unit voltage change, i.e., a change in the sensitivity. As a result, the synthesizer is less influenced by disturbance noise.

By increasing the number of the voltage selection circuits, the flat portion of the change in the synthesized capacitance of the variable capacitive element shown in the bottom of FIG. 10B, i.e., the flat range of the sensitivity, extends. By providing a larger number of DA converters in the DA conversion section 6, the sensitivity is closer to the flat shape.

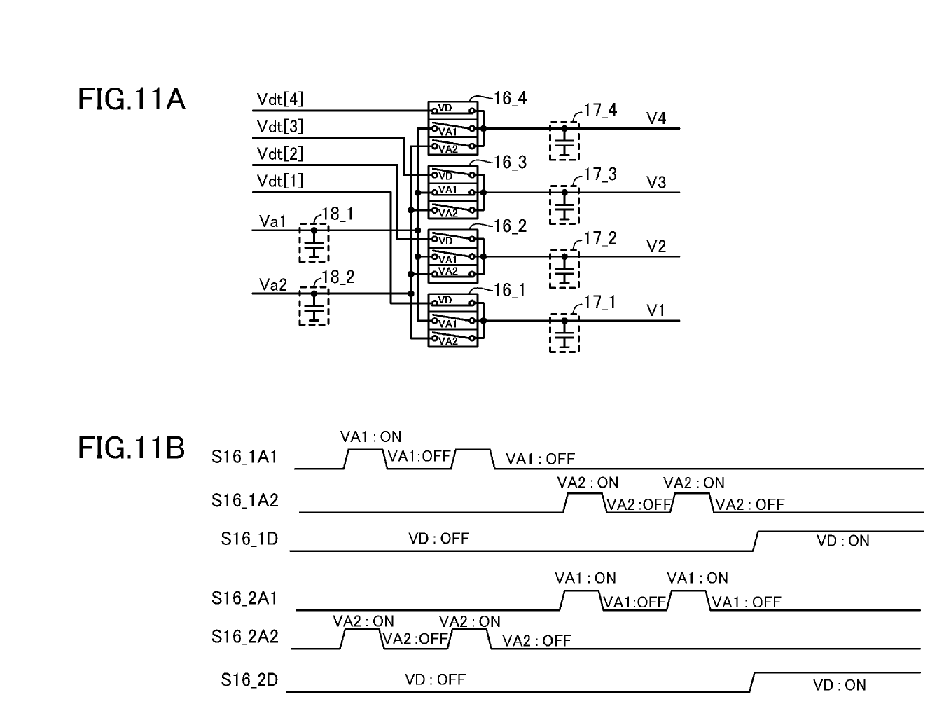

In each of the voltage selection circuits 16_1-16_4, the VA1 terminal, the VA2 terminal, and the VD terminal may be transiently turned on at the same time. Malfunction caused by the simultaneous turn-on is preferably prevented. FIGS. 11A and 11B illustrate control for preventing simultaneous turn-on of the VA1 terminals, the VA2 terminals, and the VD terminals of the voltage selection circuits 16_1-16_4. FIG. 11A illustrates more detailed configurations of the voltage selection circuits 16_1-16_4. FIG. 11B illustrates example timing of control signals of the voltage selection circuits 16_1 and 16_2. Although not shown, for example, in the voltage selection circuit 16_1, the on/off state of the VA1 terminal is controlled with a control signal S16_1A1, the on/off state of the VA2 terminal is controlled with a control signal S16_1A2, and the on/off state of the VD terminal is controlled with a control signal S16_1D. Simultaneous activation of S16_1A1, S16_1A2, and S16_1D is prevented, thereby preventing simultaneous turn-on of the VA1 terminal, the VA2 terminal, and the VD terminal.

As shown in FIG. 11B, the signals S16_1A1 and S16_2A1 controlling the on/off state of the VA1 terminals, and the signals S16_1A2 and S16_2A2 controlling the on/off state of the VA2 terminals may not be continuously active, but may be temporally discretely active. This reduces malfunction caused by a transient change in the output voltages Va1 and Va2 at the moment of changing DL[1]-DL[n] input to the DA converters 61 and 62.

Since V1-V4 are control voltages of the variable capacitive elements, even when the VA1 terminal, the VA2 terminal, and the VD terminal of each voltage selection circuit are turned off at the same time, the voltage before the turn-off is held at the variable capacitive element. In addition, as shown in FIG. 11A, LPFs 17_1-17_4 being capacitive elements etc., may be added to the outputs of the voltage selection circuits 16_1-16_4 to reduce a voltage change due to leakage etc. Similarly, LPFs 18_1 and 18_2 being capacitive elements etc., may be added to the outputs of the DA converters 61 and 62 to reduce malfunction caused by transient response of the DA converters 61 and 62.

### Variation

The DA converters 61 and 62 may have different output voltage ranges. For example, the output voltage range of the DA converter 61 may be from VL to VM′, and the output voltage range of the DA converter 62 may be from VM to VH′.

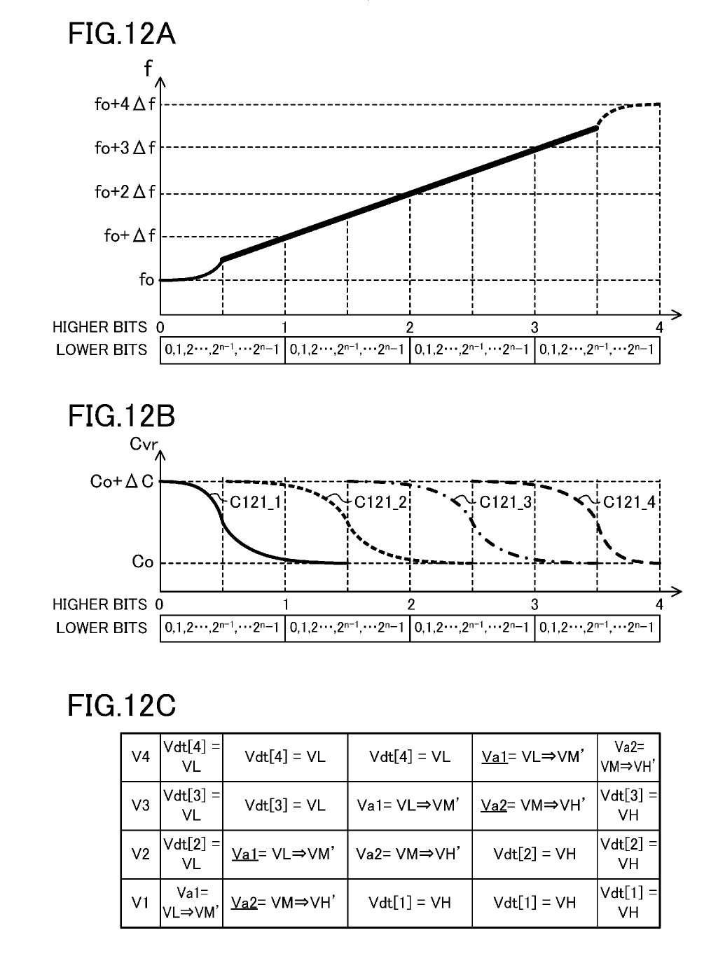

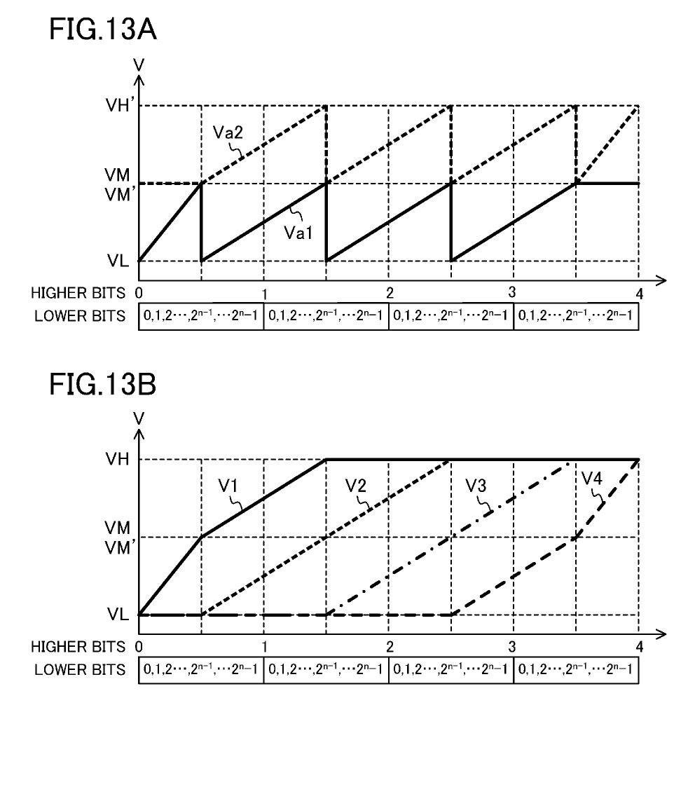

FIGS. 12A-13B illustrate operation of a frequency synthesizer according to a variation. In each graph of FIGS. 12A, 12B, 13A, and 13B, the horizontal axis represents digital control data output from a loop gain control section 5. In FIG. 12A, the vertical axis represents the oscillation frequency of an oscillation section 1. In FIG. 12B, the vertical axis represents the capacitance of variable capacitive elements 121_1-121_4. In FIG. 13A, the vertical axis represents the values of Va1 and Va2. In FIG. 13B, the vertical axis represents the values of V1-V4. In FIG. 12C, the vertical axis represents output voltages V1-V4 of voltage selection circuits 16_1-16_4.

As shown in FIG. 13A, Va1 varies from VL to VM′, and Va2 varies from VM to VH′. Thus, as shown in FIG. 12C, when V1-V4 need to be within the range from VL to VM′, Va1 may be selected. When V1-V4 need to be within the range from VM to VH′, Va2 may be selected. In FIG. 12C, what is different from FIG. 8C is underlined. In comparison between the operational illustrations of FIGS. 8A-9B and FIGS. 12A-13B, only the change in Va1 and Va2, and the selection control of V1-V4 are different. The change of the variable capacitive elements 121_1-121_4 and the change in the oscillation frequency of the oscillation section 1 are the same. That is, in this variation as well, the frequency synthesizer is less influenced by disturbance noise.

In this variation, since the output voltage ranges of the DA converters 61 and 62 can be narrowed, for example, the graduation number necessary to obtain the same voltage resolution ΔV is halved, thereby reducing the bit number of the lower bits by 1 bit. Alternatively, the voltage resolution ΔV may be halved without reducing the bit number of the lower bits to improve the accuracy.

### Fourth Embodiment

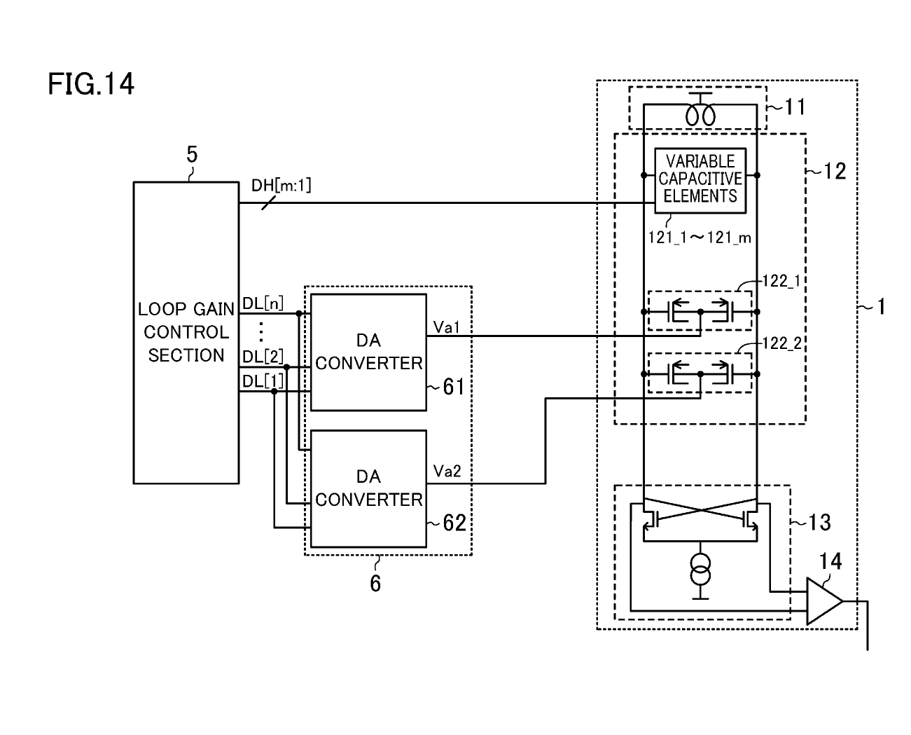

FIG. 14 illustrates a configuration of a part of a frequency synthesizer according to a fourth embodiment. The entire configuration is similar to that in the first embodiment. Differences from the first to third embodiments will be described below.

In the frequency synthesizer according to this embodiment, a DA conversion section 6 includes two DA converters 61 and 62 performing DA conversion of at least part of bits, for example, lower n bits DL[1]-DL[n] of an output of a loop gain control section 5. A variable capacitive section 12 includes a plurality of variable capacitive elements 121_1-121_{—}m, 122_1, and 122_2, which are coupled in parallel.

The variable capacitive elements 121_1-121_{—}m are directly controlled with the higher m bits DH[1]-DH[m] of the output of the loop gain control section 5. On the other hand, the DA converters 61 and 62 convert the lower n bits DL[1]-DL[n] of the output of the loop gain control section 5 to the analog voltages Va1 and Va2. Va1 controls the variable capacitive element 122_1. Va2 controls the variable capacitive element 122_2.

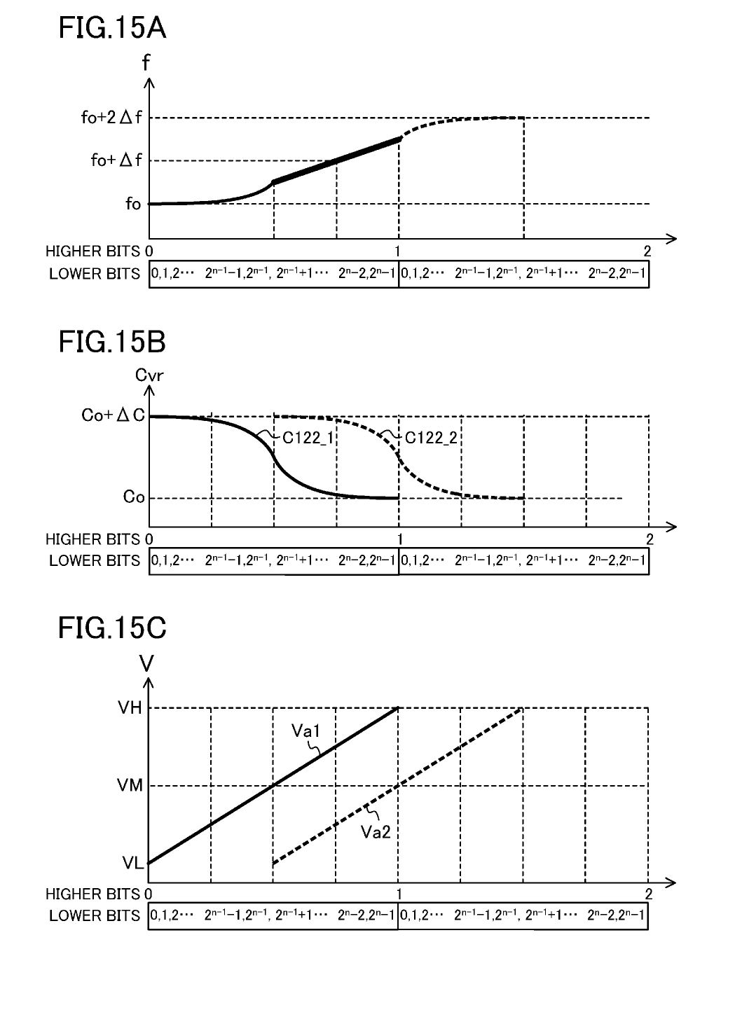

FIGS. 15A-15C illustrate operation of the frequency synthesizer according to this embodiment. In each graph of FIGS. 15A-15C, the horizontal axis represents digital control data output from the loop gain control section 5. In FIG. 15A, the vertical axis represents the oscillation frequency of an oscillation section 1. In FIG. 15B, the vertical axis represents the capacitance of the variable capacitive elements 122_1 and 122_2. In FIG. 15C, the vertical axis represents the values of Va1 and Va2. As shown in FIG. 15C, the operation ranges of the DA converters 61 and 62 are shifted from each other so that Va2 becomes low sensitive VL when Va1 is high sensitive VM, and so that Va1 becomes low sensitive VH when Va2 is high sensitive VM. In this manner, the change in the synthesized capacitance of the variable capacitive elements 122_1 and 122_2 is flat. Then, as shown in FIG. 15A, the change in the oscillation frequency of the oscillation section 1 is close to a straight line and a rapid change in the oscillation frequency is reduced.

As described above, the first to fourth embodiments have been described as example techniques disclosed in the present application. However, the techniques according to the present disclosure are not limited to these embodiments, but are also applicable to those where modifications, substitutions, additions, and omissions are made. In addition, elements described in the first to fourth embodiments may be combined to provide a different embodiment.

Various embodiments have been described above as example techniques of the present disclosure, in which the attached drawings and the detailed description are provided.

As such, elements illustrated in the attached drawings or the detailed description may include not only essential elements for solving the problem, but also non-essential elements for solving the problem in order to illustrate such techniques. Thus, the mere fact that those non-essential elements are shown in the attached drawings or the detailed description should not be interpreted as requiring that such elements be essential.

Since the embodiments described above are intended to illustrate the techniques in the present disclosure, it is intended by the following claims to claim any and all modifications, substitutions, additions, and omissions that fall within the proper scope of the claims appropriately interpreted in accordance with the doctrine of equivalents and other applicable judicial doctrines.

What is claimed is:

1. A frequency synthesizer whose oscillation frequency is digitally controlled comprising:
a loop gain control section configured to generate digital control data for controlling a loop gain of the frequency synthesizer;
a DA conversion section configured to convert lower bits of the digital control data to an analog voltage; and
an oscillation section configured to oscillate at a frequency corresponding to higher bits of the digital control data and the analog voltage output from the DA conversion section.

2. The frequency synthesizer of claim 1, wherein
the oscillation section includes
a thermometer converter configured to convert the higher bits of the digital control data to a thermometer code,
a plurality of voltage selection circuits, each corresponding to one of a plurality of given bits of the thermometer code, and configured to selectively output either one of a voltage of corresponding one of the given bits or the analog voltage output from the DA conversion section, and
a plurality of variable capacitive elements coupled in parallel, each having capacitance controlled in accordance with a voltage of one of the bits of the thermometer code, which is applied to none of the voltage selection circuits, or an output voltage of corresponding one of the plurality of voltage selection circuit.

3. The frequency synthesizer of claim 2, wherein
the DA conversion section includes a plurality of DA converters each configured to convert corresponding one of the lower bits of the digital control data to an analog voltage, and
each of the plurality of voltage selection circuits selectively outputs any one of the voltage of the corresponding one of the given bits of the thermometer code and the analog voltages output from the plurality of DA converters.

4. The frequency synthesizer of claim 3, wherein
the plurality of DA converters output different analog voltages from a common input.

5. The frequency synthesizer of claim 3, wherein
output voltage ranges of the plurality of DA converters are different from each other, and narrower than voltage change ranges of the bits of the thermometer code.

6. The frequency synthesizer of claim 2, wherein
a control signal instructing the voltage selection circuits to select the analog voltage output from the DA conversion section is temporally discretely active.

7. The frequency synthesizer of claim 3, wherein
a control signal instructing the voltage selection circuits to select the analog voltage output from the DA conversion section is temporally discretely active.

8. The frequency synthesizer of claim 2, wherein
the oscillation section includes LPFs coupled to outputs of the voltage selection circuits.

9. The frequency synthesizer of claim 3, wherein
the oscillation section includes LPFs coupled to outputs of the voltage selection circuits.

10. The frequency synthesizer of claim 2, further comprising:
an LPF coupled to an output of the DA conversion section.

11. The frequency synthesizer of claim 3, further comprising:
an LPF coupled to an output of the DA conversion section.

12. The frequency synthesizer of claim 8, further comprising:
an LPF coupled to an output of the DA conversion section.

13. The frequency synthesizer of claim 9, further comprising:
an LPF coupled to an output of the DA conversion section.

14. The frequency synthesizer of claim 1, wherein
the oscillation section includes
a plurality of first variable capacitive elements coupled in parallel, each having capacitance controlled with one of the higher bits of the digital control data, and
a second variable capacitive element coupled in parallel to the plurality of first variable capacitive elements, and having capacitance controlled with the analog voltage output from the DA conversion section, and
a change amount of the capacitance of the second variable capacitive element corresponds to weighting of a least significant bit of the higher bits.

15. A frequency synthesizer whose oscillation frequency is digitally controlled comprising:
a loop gain control section configured to generate digital control data for controlling a loop gain of the frequency synthesizer;
a DA conversion section configured to convert at least some of bits of the digital control data to an analog voltage; and
an oscillation section whose oscillation frequency is variable with the analog voltage output from the DA conversion section, wherein
the DA conversion section includes a plurality of DA converters, each configured to convert lower bits of the digital control data to an analog voltage, and
the plurality of DA converters output different analog voltages from a common input.
